(19) United States
(12) Patent Application Publication
(10) Pub. No.: US 2001/0050146 A1
(43) Pub. Date: Dec. 13, 2001

(54) Substrate processing apparatus and substrate processing method

(75) Inventors: Kazuhiro Shimeno, Tokyo (JP); Ken Yoshioka, Yamaguchi-ken (JP)

Correspondence Address: OLIFF & BERRIDGE, PLC, P.O. BOX 19928, ALEXANDRIA, VA, 22320, US

(73) Assignee: HITACHI KOKUSAI ELECTRIC INC. HITACHI LTD.

(21) Appl. No.: 09/790,615

(22) Filed: Feb. 23, 2001

(30) Foreign Application Priority Data
Aug. 7, 1998 (JP) 10-224694

(51) Int. Cl. H01L 21/00; C23C 16/00

(52) U.S. Cl. 156/345; 118/715; 118/729

(57) ABSTRACT

To prevent contamination of a substrate by natural oxide film etc in the inside-apparatus transfer period, a CVD apparatus is provided with a wafer deposition part 10 and a wafer transfer part 30. Wafer transfer part 30 includes cassette mounting bases 31(1), 31(2), 31(3), 31(4), wafer transfer chamber 32, cover opening/closing mechanisms 33(1), 33(2), 33(3), and 33(4) and a wafer transfer robot 34. Transferring of a wafer 51 between cassette 52 mounted on cassette mounting bases 31(1), 31(2), 31(3), 31(4) and water deposition part 10 is performed through a sealed space provided by wafer transfer chamber 32. This sealed space is cleansed by inert gas by means of a vacuum evacuation line 35, inert gas supply line 36, oxygen concentration detector 37 and control part 38.

### BACKGROUND OF TH E INVENTION

1. Field of the Invention

The present invention relates to a substrate processing apparatus and substrate processing method whereby prescribed processing is performed on a substrate of a solid-state device.

2. Description of the Related Art

In general, the quality of semiconductor devices is dependent on the amount of contamination of the wafer produced by dirt and/or natural oxide film. That is, when the amount of contamination of the wafer due to the natural oxide film etc increases, quality is lowered and when the amount of contamination is less quality is improved. Consequently, in a wafer processing apparatus that performs prescribed processing (film processing or etching processing etc) on the wafer, a technique is desired whereby the amount of contamination of the wafer produced by natural oxide film may be lowered.

In order to respond to this demand, in a conventional wafer processing apparatus, a load lock chamber (hereinbelow called a “cassette chamber”) was provided accommodating a cassette for accommodating the wafer, and insertion/removal of the wafer was performed through this cassette chamber.

In such a construction, when a cassette is accommodated in the cassette chamber, the cassette chamber is cleansed by vacuum evacuation or by inert gas. The wafer is therefore arranged in vacuum or an inert gas atmosphere or during the period from its introduction into the cassette chamber until it has been subjected to prescribed processing (hereinbelow termed the “awaiting processing period”) and during the period after completion of processing until it is removed from the cassette chamber (hereinbelow termed the “awaiting removal period”). As a result, contamination of the wafer by natural oxide film etc. is reduced.

However, with this arrangement, the wafer is exposed to the atmosphere during the period in which it is being transferred between wafer processing apparatuses (hereinbelow termed the “between-apparatus transfer period”). This is because, in a conventional wafer processing apparatus, an open-type cassette is employed for the cassette. As used herein, an “open type cassette” means a cassette whose interior is normally open to the outside via the wafer insertion/removal aperture.

Consequently, with such an arrangement, in the between-apparatus transfer period, the wafer is contaminated by natural oxide film etc. As a result, with such an arrangement, there was the problem that it was not possible to cope with recent demands for higher densities of integration of semiconductor devices.

In order to cope with this problem, in recent years, the use of closed type cassettes in wafer processing apparatuses in which 12-inch wafers are processed has been studied. As used herein, a closed-type cassette means a cassette whose interior is open to the outside only during insertion/removal of the wafer.

In an arrangement in which a closed type cassette is employed as the cassette, the wafer is not exposed to the atmosphere in the between-apparatus transfer period. With this constructions contamination of the wafer by natural oxide film etc during the between-apparatus transfer period is prevented. As a result, demands for higher densities of integration of semiconductor devices can be coped with.

A closed type cassette is usually called a “pod-type” cassette. Such a pod-type cassette comprises a body having a wafer insertion/removal port and a cover for blocking the wafer insertion/removal port of this body.

A conventional pod-type cassette of this kind is disclosed in Laid-open Japanese Patent Application NO. H 8-279546- In such a cassette, the wafer insertion/removal port is provided at the front of the body. The “front of the body” means the portion on the insertion side when the cassette is inserted into the apparatus. For this reason, such a cassette is usually called a FOUP (front opening unified pod).

In an arrangement in which a pod-type cassette is employed as the cassette, a cover opening/closing mechanism is required for opening/closing the cassette cover. In this reference, this cover opening/closing mechanism was arranged outside the apparatus body (wafer processing part) and the cover was arranged to be opened/closed in an atmosphere constituted by the external atmosphere.

However, with such an arrangement, the wafer is exposed to the atmosphere during the period (hereinbelow called the “inside-apparatus transfer period”) in which it is transferred between the position of its introduction into the apparatus and the apparatus body, which is provided In a position different from the wafer introduction position. With this arrangement, the wafer is therefore contaminated by natural oxide film etc. during the inside-apparatus transfer period.

The amount of this contamination is much smaller than the amount of contamination when an open-type cassette is employed. However, demands for increased density of integration of semiconductor devices are becoming increasingly severe. In the quest for higher density of Integration of semiconductor devices, even such a minute amount of contamination cannot therefore be neglected.

An object of the present invention is therefore to provide a substrate processing apparatus and substrate processing method whereby contamination of the substrate by natural oxide film etc during the period of inside-apparatus transfer can be prevented.

### SUMMARY OF THE INVENTION

To solve the above problem, a substrate processing apparatus of a first invention comprises a substrate processing part and a substrate transfer part, and the substrate transfer part comprises a plurality of substrate accommodating body holding part, a transfer part side substrate transfer space provision part, a cleansing part, a substrate introduction/removal port opening/closing part; and a transfer part side substrate transfer part.

The substrate processing part is a portion that performs the prescribed processing on a substrate and is provided in a position different from the substrate introduction position where the substrate accommodated in a substrate accommodating body of sealed construction having a substrate introduction/removal port at the side is introduced. Also, the substrate transfer part is a portion that transfers the substrate between the substrate introduction position and the substrate processing part.

In the substrate transfer part, each of the plurality of substrate accommodating body holding parts is a portion that holds respectively the substrate accommodating body at the substrate introduction position. Also, the transfer part side substrate transfer space provision part is a portion that provides a sealed transfer part side substrate transfer space which is a space for transferring the substrate between the substrate accommodating body that is held In the substrate accommodating body holding part and the substrate processing part and pressure of which is set at atmospheric pressure. Also, the cleansing part is a portion that cleanses with inert gas the transfer part side substrate transfer space when the substrate is transferred through the transfer part side substrate transfer space between the substrate accommodating body held in the substrate accommodating body holding part and the substrate processing part.

Also, the substrate introduction/removal port opening/closing part is a portion that opens/closes the substrate introduction/removal port of the substrate accommodating body held in the substrate accommodating body holding part in a condition in which the transfer part side substrate transfer space has been cleansed by the cleansing part. This substrate introduction/removal port opening/closing part is arranged in the transfer part side substrate transfer space. Also, the transfer part side substrate transfer part is a portion that transfers the substrate between the substrate accommodating body whose substrate introduction/removal port has been opened by the substrate introduction/removal port opening/closing part and the substrate processing part. This transfer part side substrate transfer part is arranged in the transfer part side substrate transfer space.

In the above construction, when the substrate accommodating body is held by the substrate accommodating body holding part, the transfer part side substrate transfer space is cleansed by the cleansing part. When this cleansing condition reaches a prescribed condition, the substrate introduction/removal port of the substrate accommodating body is opened by the substrate introduction/removal port opening/closing part. When this processing is completed, the substrate accommodated in the substrate accommodating body is transferred to the substrate processing part by the transfer part side substrate transfer part, and subjected to prescribed processing. When this processing has been completed, the substrate that has been subjected to this processing is transferred to the substrate accommodating body by the transfer part side substrate transfer part.

As described above, with the apparatus of the first invention, when the substrate is transferred between the substrate introduction position and the substrate processing part, the substrate is transferred through a sealed space cleansed by inert gas. Contamination of the substrate by natural oxide film etc. during the inside-apparatus transfer period can thereby be prevented. Also, existing substrate processing apparatuses can be utilized practically without modification.

In the substrate processing apparatus according to a second invention, in the apparatus set out in the first invention, the substrate processing part comprises a substrate processing space provision part, a substrate standby space provision part, a processing part side substrate transfer space provision part, a processing part side substrate transfer part and a substrate holding part

The substrate processing space provision part is a portion that provides a sealed substrate processing space for performing the prescribed processing on the substrate. Also, the substrate standby space provision part is a portion that provides a sealed substrate standby space for temporarily holding the substrate in standby. Also, the processing part side substrate transfer space provision part is a portion that provides a sealed processing part side substrate transfer space for transferring the substrate between the substrate standby space and the substrate processing space.

Also, the processing part side substrate transfer part is a portion that transfers the substrate between the substrate standby space and the substrate processing space. This processing part side substrate transfer part is arranged In the processing part side substrate transfer space. Also, the substrate holding part is a portion that holds the substrate that is transferred into the substrate standby space. This substrate holding part is arranged in the substrate standby space.

In the above construction, a substrate accommodated in the substrate accommodating a body is transferred to the substrate standby space by the transfer part side substrate transfer part. This transfer substrate is subjected to prescribed processing on being transferred into the substrate processing space by the processing part side substrate transfer part. This process substrate is transferred into the substrate standby space by the processing part side substrate transfer part. The substrate that is transferred therefrom is transferred into the substrate accommodating body by the transfer part side substrate transfer part.

As described above, with the apparatus of the second invention, the substrate holding part constitutes a buffering mechanism of the transfer part side substrate transfer processing and the processing part side substrate transfer processing. The transfer part side substrate transfer processing means substrate transfer processing between the substrate accommodating body and substrate standby space. Also, the processing part side substrate transfer processing means substrate transfer processing between the substrate standby space and the substrate processing space. Independence of the transfer part side substrate transfer processing and processing part side substrate transfer processing can thereby be achieved. As a result, the throughput of the substrate processing apparatus can be Improved.

Further the substrate holding part is for example constructed so as to be capable of holding a plurality of substrates.

With the above construction, substrates transferred into the substrate standby space by the transfer part side substrate transfer part and processing part side substrate transfer part can be held concurrently. That is, in a condition in which a substrate transferred by the substrate transfer part on one side is held, a substrate transferred by the substrate transfer part on the other side can also be held.

In this way, substrate transfer processing from the substrate accommodation body to the substrate standby space and substrate transfer processing from the substrate standby space to the substrate processing space can be performed independently. Also, substrate transfer processing from the substrate processing space to the substrate standby space and substrate transfer processing from the substrate standby space to the substrate accommodation body can be performed independently. As a result, the independence of transfer part side substrate transfer processing and processing part side substrate transfer processing can be improved.

In the substrate processing apparatus of a third invention, in an apparatus according to the second invention, the substrate holding part is a substrate mounting shelf comprising a substrate introduction/removal port whereby introduction/removal of the substrate is effected.

With the above construction, the substrate holding part can be constructed in a brief manner.

In the substrate processing apparatus of a fourth invention, in an apparatus according to the third invention, the substrate mounting shelf, as the substrate introduction/removal ports. comprises a transfer part side substrate introduction/removal port and a processing part side substrate introduction/removal port.

The transfer part side substrate introduction/removal port is a substrate introduction/removal port whereby introduction/removal of the substrate is performed by the transfer part side substrate transfer part. The processing part side substrate introduction/removal port is a substrate introduction/removal port whereby introduction/removal of the substrate is performed by the processing part side substrate transfer part.

With the above construction, even when access of the substrate mounting shelf by the transfer part side substrate transfer part and processing part side substrate transfer part occurs simultaneously, there is no need to effect adjustment in respect of conflict thereof. The throughput of the substrate processing apparatus can thereby be improved.

In the substrate processing apparatus of a fifth invention, in the apparatus according to the fourth invention, the access directions of the substrate mounting shelf by the transfer part side substrate transfer part and the processing part side substrate transfer part are set in different directions. Also, in this apparatus, the substrate mounting shelf is constructed so as to absorb the difference of the access directions by suitable setting of at least one of the positions, orientations and widths of the transfer part side substrate introduction/removal port and the processing part side substrate introduction/removal port.

With such a construction, the difference of access direction of the substrate mounting shelf relating to the two substrate transfer parts can be absorbed by a brief construction.

In the substrate processing apparatus according to a sixth invention, in an apparatus according to the fifth invention, the substrate mounting shelf is constructed so as to hold the substrate by means of a plurality of support pillars having grooves in which the periphery of the substrate is inserted. Also, in this apparatus, the transfer part side substrate introduction/removal port and the processing part side substrate introduction/removal port of the substrate mounting shelf are respectively set between two adjacent support pillars of the plurality of support pillars. Furthermore, in this apparatus, when the positions of the transfer part side substrate introduction/removal port and the processing part side substrate introduction/removal port are suitably set, the portion are set by suitable setting of the depths of the grooves. Likewise, in this apparatus, when the orientations of the transfer part side substrate introduction/removal port and the processing part side substrate introduction/removal port are suitably set, the orientations are set by suitable setting of the position of arrangement of the two adjacent support pillars. Also, in this apparatus, when the widths of the transfer part side substrate introduction/removal port and the processing part side substrate introduction/removal port are suitably set, the widths are set by suitable setting of the position of arrangement of the two adjacent support pillars.

With such a construction, the positions, orientations and widths of the transfer part side substrate introduction/removal port and processing part side substrate Introduction/removal port can be suitably set by means of a brief construction.

In the substrate processing apparatus according to a seventh invention, in the apparatus according to the fourth invention, the access directions of the substrate mounting shelf by the transfer part side substrate transfer part and the processing part side substrate transfer part are set in different directions. Also, this apparatus further comprises a rotary drive part that drives the substrate mounting shelf in rotation.

The rotary drive part drives the substrate mounting shelf In rotation such that, when the substrate mounting shelf is accessed by the transfer part side substrate transfer part. the transfer part side substrate introduction/removal port faces the direction of access of the substrate mounting shelf by the transfer part side substrate transfer part. In contrast, when the substrate mounting shelf is accessed by the processing part side substrate transfer part, it drives the substrate mounting shelf in rotation such that the processing part side substrate Introduction/removal port faces the direction of access of the substrate mounting shelf by the processing part side substrate transfer part.

With such a construction, it is possible to employ as the substrate mounting shelf a substrate mounting shelf identical with that which would be used if the direction of access of the substrate mounting shelf by the transfer part side substrate transfer part and the processing part side substrate transfer part were the same. This facilitates manufacture of the substrate mounting shelf.

Also, with such a construction, a substrate mounting shelf having two plate-shaped support pillars can be employed as the substrate mounting shelf. The substrate can thereby be held in stable fashion.

Also, with such a construction, as a result, the access directions of the substrate mounting shelf by the transfer part side substrate transfer part and processing part side substrate transfer part can be aligned. The crystal orientation of the substrate in the substrate processing space can thereby be set to a desired orientation. As a result, the substrate processing characteristics can be improved compared with a case in which the crystal orientation is offset from the desired orientation.

In the substrate processing apparatus according to a eighth invention, in the apparatus according to the first invention, the cleansing part comprises a vacuum evacuation part, an inert gas supply part, an oxygen concentration detection part, and a control part.

The vacuum evacuation part is a portion that evacuates the atmosphere of the transfer part side substrate transfer space. The inert gas supply part is a portion that supplies inert gas to the transfer part side substrate transfer space. The oxygen concentration detection part is a portion that detects the oxygen concentration of the transfer part side substrate transfer space. The control part is a portion that controls the operation of the inert gas supply part such that, if the oxygen concentration detected by the oxygen concentration detection part exceeds a prescribed value, supply processing of the inert gas is conducted and if it is less than the prescribed value this supply processing is stopped.

In such a construction, when the transfer part side substrate transfer space is cleansed, the atmosphere of this space is evacuated to vacuum by the vacuum evacuation part. Also, inert gas is supplied into this space by the inert gas supply part. Furthermore, the oxygen concentration of this space is detected by the oxygen concentration detection part. Also, the operation of the inert gas supply part is controlled by the control part in accordance with the result of this detection. In this way, when the oxygen concentration of the transfer part side substrate transfer space exceeds a prescribed value, supply processing of inert gas is executed, and when this is less than the prescribed value, this supply processing is stopped.

With such a construction, inert gas is supplied into this space only when the oxygen concentration of the transfer part side substrate transfer space is less than the prescribed value. The consumption of inert gas can thereby be reduced compared with a construction in which inert gas is constantly supplied.

In the substrate processing method according to ninth invention, when a substrate is transferred between a plurality of substrate accommodating body holding parts and a substrate processing part, the substrate is transferred through a sealed space cleansed by inert gas.

The plurality of substrate accommodating body holding parts are portions each of which holds respectively a substrate accommodating body of sealed construction having a substrate introduction/removal port at the side. These substrate accommodating body holding parts are provided at a substrate introduction position where the substrate accommodated in the substrate accommodating body is introduced. The substrate processing part is a portion that performs prescribed processing on the substrate. This substrate processing body is provided at a position different from the substrate introduction position.

With such arrangement, just as in the case of the substrate processing apparatus of the first invention, contamination of the substrate during the inside-apparatus transfer period by natural oxidation etc. can be prevented.

### BRIEF DESCRIPTION OF THE DRAWINGS

FIG. 1 is a plan view illustrating the layout of a first embodiment of the present invention;

FIG. 2 is a side view illustrating the layout of the first embodiment of the present invention;

FIG. 3 is a perspective view illustrating the layout of the first embodiment of the present invention;

FIG. 4 is a view illustrating the movement track etc of a wafer in the first embodiment of the present invention;

FIGS. 5A, 5B and 5C are a sequence diagram given in explanation of the operation of the first embodiment of the present invention;

FIGS. 6A and 6B are views showing the construction of a wafer mounting shelf in the first embodiment of the present invention;

FIG. 7 is a cross-sectional view showing the layout of the wafer mounting shelf of the first embodiment of the present invention;

FIGS. 8A and 8B are views given in explanation of the benefits of the wafer mounting shelf of the first embodiment of the present invention;

FIG. 9 is a cross-sectional view illustrating the layout of major parts of a second embodiment of the present invention;

FIG. 10 is a cross-sectional view illustrating the layout of major parts of a third embodiment of the present invention;

FIG. 11 is a side view illustrating the layout of a fourth embodiment of the present invention;

FIGS. 12A and 12B are views given in explanation of the operation of the fourth embodiment of the present invention;

FIG. 13 is a view given in explanation of the benefits of the fourth embodiment of the present invention;

FIG. 14 is a view given in explanation of the benefits of the fourth embodiment of the present invention;

FIG. 15 is a view given in explanation of the benefits of the fourth embodiment of the present invention;

FIGS. 16A, 16B and 16C are views given in explanation of the benefits of the fourth embodiment of the present invention;

FIGS. 17A, 17B and 17C are views given in explanation of the benefits of the fourth embodiment of the present invention; and

FIGS. 18A, 18B, 18C and 18D are views given in explanation of the benefits of the fourth embodiment of the present invention.

### DESCRIPTION OF THE PREFERRED EMBODIMENTS

Preferred embodiments of the present invention are described below with reference to the drawings.

### [1] First Embodiment

### [1-1] Construction of the Substrate Processing Apparatus

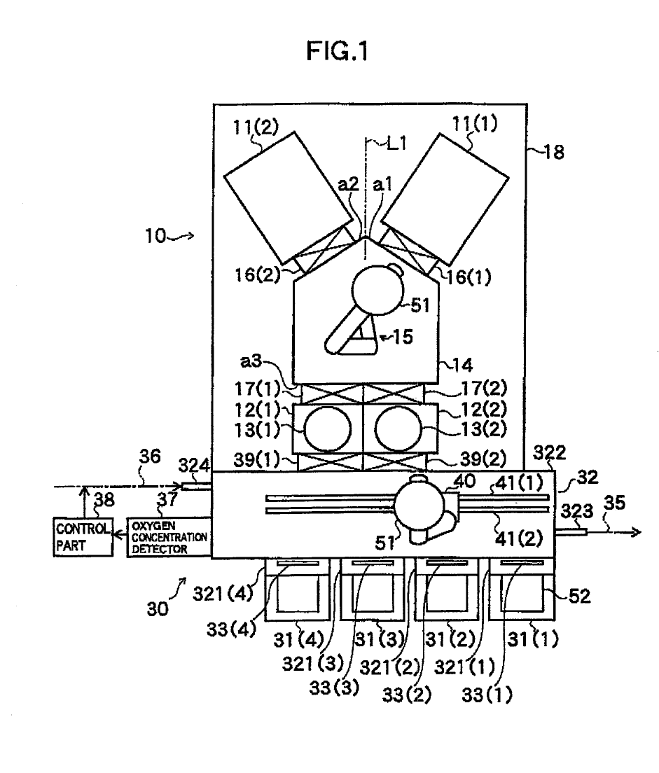

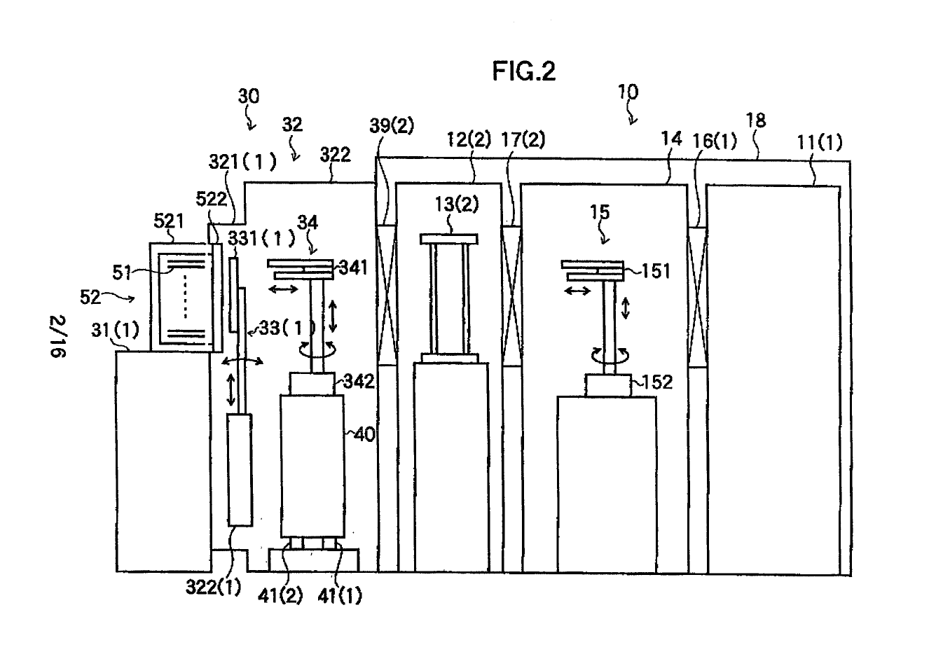

FIG. 1 is a plan view illustrating the construction of a first embodiment of a substrate processing apparatus according to the present invention and FIG. 2 is likewise a side view thereof. The Figures show the case where the present invention is applied, by way of example, to a single wafer cluster type CVD (chemical vapor deposition) apparatus. Part of the Figure is shown transparently.

The CVD apparatus illustrated comprises for example a wafer deposition part 10 and a wafer transfer part 30. The wafer deposition part 10 is a portion in which a prescribed thin film is formed on a wafer 51 using a chemical reaction. This wafer deposition part 10 is provided in a position different from the position where the wafer 51 is introduced into the apparatus. Also, the wafer transfer part 30 is a portion whereby the wafer 51 is transferred between the wafer introduction position and the wafer deposition part 10.

The wafer deposition part 10 comprises for example two reaction chambers 11(1), 11(2), two wafer standby chambers 12(1), 12(2), two wafer mounting shelves 13(1). 13(2), a single wafer transfer chamber 14, and a single wafer transfer robot 15.

The reaction chambers 11(1), 11(2) are compartments providing a sealed reaction space for forming a prescribed thin film by using a chemical reaction on the surface of the wafer 51. Also, the wafer standby chambers 12(1), 12(2) are load lock chambers providing a sealed wafer standby space wherein the wafer 51 can be temporarily held in standby. Also, the wafer mounting shelves 13(1), 13(2) are shelves on which the wafers 51 are placed that have been transferred into the wafer standby chambers 12(1), 12(2).

Also, the wafer transfer chamber 14 is a load lock chamber for providing a sealed wafer transfer space for transferring a wafer between the reaction chambers 11(1), 11(2) and the wafer standby chambers 12(1), 12(2). Also, the wafer transfer robot 15 is a robot for transferring the wafer 51 between the reaction chambers 11(1), 11(2) and the standby chambers 12(1), 12(2).

The reaction chambers 11(1), 11(2) are connected with the transfer chamber 14 through respective gate valves 16(1), 16(2). Likewise, the wafer standby chambers 12(1), 12(2) are connected with the transfer chamber 14 through respective gate valves 17(1), 17(2).

The wafer mounting shelves 13(1), 13(2) are respectively arranged within the interior (wafer standby space) of the wafer standby chambers 12(1), 12(2). The construction of these wafer mounting shelves 13(1), 13(2) will be described in detail later. The wafer transfer robot 15 is arranged in the interior (wafer transfer space) of the wafer transfer chamber 14.

As shown in FIG. 2, this wafer transfer robot 15 comprises a robot arm 151 and an arm drive part 152. This robot arm 151 may be constituted for example as three arm parts linked by three links. The arm drive part 152 is arranged to execute extending/retracting drive, rotary drive and raising/lowering drive of the robot arm 151.

The wafer transfer chamber 14 is formed for example as a five-cornered box shape. This wafer transfer chamber 14 is formed with axial symmetry with respect to the straight line Li. Hereinbelow, this straight line L1 is termed the center line of the wafer transfer chamber 14.

The reaction chambers 11(1), 11(2) are arranged with axial symmetry with respect to this center line L1. Likewise, the wafer standby chambers 12(1), 12(2) are arranged with axial symmetry with respect to this center line L1. In this case, the reaction chambers 11(1), 11(2) are arranged at the positions of the two sides a1, a2 respectively intersecting the center line L1 in inclined fashion. In contrast, the standby chambers 12(1), 12(2) are arranged at the position of a single side a3 intersecting center line L1 at right angles

Also, the reaction chamber 11(1) and the wafer standby chamber 12(1) are arranged so as to be positioned on opposite sides with respect to the center line L1. Likewise, the reaction chamber 11(2) and the wafer standby chamber 12(2) are arranged so as to be positioned on opposite sides with respect to the center line L1.

The reaction chambers 11(1), 11(2) and the wafer standby chambers 12(1), 12(2) etc are accommodated in a frame 18.

The wafer transfer part 30 comprises for example four cassette mounting bases 31(1), 31(2), 31(3), 31(4), a single wafer transfer chamber 32, four cover opening/closing mechanisms 33(1), 33(2), 33(3), and 33(4). a single wafer transfer robot 34, a vacuum evacuation line 35, an inert gas supply line 36, an oxygen concentration detector 37 and a control part 38.

The cassette mounting bases 31(1), 31(2), 31(3), 31(4) are bases on which the cassettes 52 are mounted. Each cassette 52 has for example a wafer accommodating part 521 and a cover 522 (Refer to FIG. 2). The wafer accommodating part 521 is for example square box-shaped constructed. A wafer introduction/removal port through which the wafer 51 is introduced/removed is arranged at the front of the side of the wafer accommodating part 521. This wafer introduction/removal port is closed by the cover 522. The wafer transfer chamber 32 is a load look chamber providing a sealed transfer space for transferring the wafer 51 between the cassette 52 and the wafer standby chambers 12(1), 12(2). This wafer transfer chamber 32 comprises four opening/closing mechanism accommodating parts 321(1), 321(2), 321(3), and 321(4) and a single robot accommodating part 322.

Also, the opening/closing mechanisms 33(1), 33(2), 33(3), 33(4) are mechanisms to open and close the cover 522 of the cassette 52. In other words, these opening/closing mechanism 33(1), 33(2), 33(3) and 33(4) are mechanism to open and close the wafer introduction/removed port of the wafer accommodating part 521. The wafer transfer robot 34 is a robot for transferring the wafer 51 between the cassette 52 and the wafer standby chambers 12(1) and 12(2).

Also, the vacuum evacuation line 35 is a line for vacuum evacuation of the interior (wafer transfer space) of the wafer transfer chamber 32. This vacuum evacuation line 35 is connected to evacuation part 323 of the wafer transfer chamber 32. This vacuum evacuation line 35 comprises for example a vacuum pump, evacuation piping, and an air valve etc.

Also, the inert gas supply line 36 is a line for supplying inert gas into the interior of the wafer transfer chamber 32. This inert gas supply line 36 is connected to the gas supply part 324 of the wafer transfer chamber 32. This gas supply line 36 comprises for example gas supply piping, an air valve, and a mass flow controller, etc. As the inert gas, for example N2 gas is employed.

Also, the oxygen concentration detector 37 detects the oxygen concentration of the wafer transfer chamber 32. The control part 38 controls the gas supply operation of the gas supply line 36 in accordance with the detection result of the oxygen concentration detector 37. In this case, the gas supply operation is executed when the oxygen concentration becomes more than a prescribed value and is stopped when it becomes less than a prescribed value.

The cassette mounting bases 31(1), 31(2), 31(3), 31(4) are arranged at the front face of the wafer transfer chamber 32. This wafer transfer chamber 32 is connected to the wafer standby chambers 12(1), 12(2) through the gate valves 39(1), 39(2).

The cover opening/closing mechanisms 33(1), 33(2), 33(3), and 33(4) are respectively accommodated within opening/closing mechanism accommodating parts 321(1), 321(2), 321(3), and 321(4). The wafer transfer robot 34 is accommodated in the robot accommodating part 322.

As shown in FIG. 2, the cover opening/closing mechanisms 33(n) (n=1, 2, 3, 4) comprise a cover holding part 331(n) and a drive part 332(n). The cover holding part 331(n) holds the cover 522 of the cassette 52. The drive part 332(n) is arranged to execute raising/lowering drive, and rotary drive in the forwards/reverse direction, of the cover holding part 331(n).

Like the wafer transfer robot 15, the wafer transfer robot 34 comprises a robot arm 341 and drive part 342. This wafer transfer robot 34 is hold on a moveable base 40. This moveable base 40 is slidable along rails 41(1) and 41(2). These rails 41(1), 41(2) extend in the direction of arrangement of the cassette mounting bases 31(1), 31(2), 31(3) and 31(4).

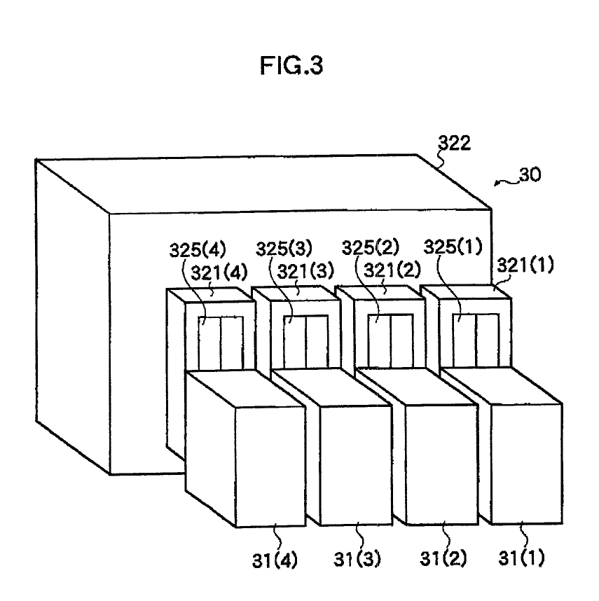

FIG. 3 is a perspective view of the wafer transfer part 30 seen from the diagonal front. Four wafer introduction/removal ports (not shown) are provided at the front faces of the opening/closing mechanism accommodating parts 321(1), 321(2), 321(3), and 321(4). These wafer introduction/removal ports are closed by doors 325(1), 325(2), 325(3), and 325(4).

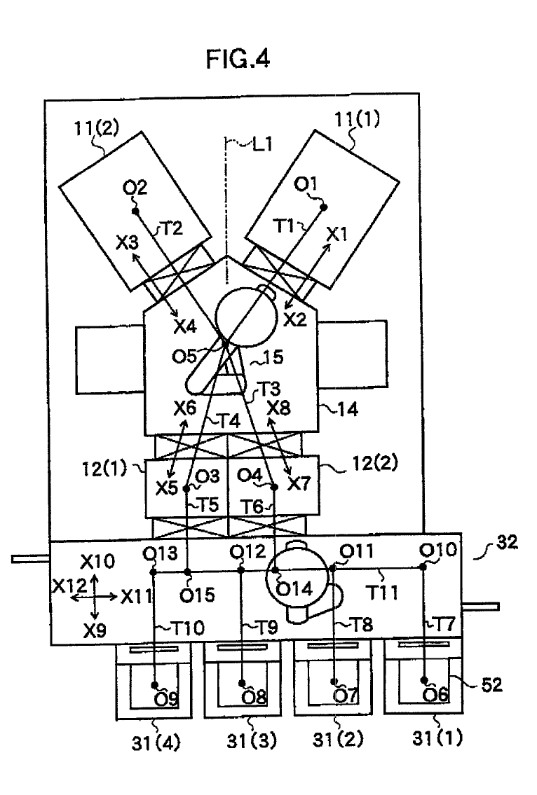

FIG. 4 is a view illustrating the track of movement of the wafer 51 and the access directions of the wafer standby chambers 12(1), 12(2) etc used by the wafer transfer robots 15, 34.

In FIG. 4, the marks X1-X2, X3-X4 respectively indicate the access directions of the reaction chambers 11(1), 11(2) used by the wafer transfer robot 15. These access directions are perpendicular with respect to the wafer introduction/removal ports of the reaction chambers 11(1), 11(2).

Likewise, the marks X5-X6, X7-X8 respectively indicate the access directions of the wafer standby chambers 12(1), 12(2) used by the wafer transfer robot 15. These access directions are not perpendicular with respect to the wafer introduction/removal ports on the side of the processing parts of the wafer standby chambers 12(1), 12(2) but are inclined on the side of center line L1 of the wafer transfer chamber 14. The wafer introduction/removal ports on the side of the processing part are the wafer introduction/removal ports facing the wafer transfer chamber 14.

The marks X9-X10 indicate the cassette 52 access directions of the wafer standby chambers 12(1), 12(2) used by the wafer transfer robot 34. These access directions are perpendicular with respect to the cassette 52 wafer introduction/removal ports and the wafer introduction/removal ports on the side of the transfer part of the wafer standby chambers 12(1), 12(2). The wafer introduction/removal ports on the side of the transfer part are the wafer introduction/removal ports of the wafer transfer part 30 facing the wafer transfer chamber 32. Also, the marks X11-X12 indicate the sliding direction of the wafer transfer robot 34 produced by the moveable base 40.

The marks 01, 02. 03, 04 indicate the centers of the wafers 51 respectively accommodated in the reaction chambers 11(1), 11(2) and the wafer standby chambers 12(1), 12(2). Also, the mark 05 indicates the center of rotation of a robot arm 151 of the wafer transfer robot 15.

Also, the marks 06, 07, 08, and 09 Indicate the centers of the wafers 51 accommodated in the cassette 52 respectively on the cassette mountings 31(1), 31(2), and 31(1), and 31(2). Also, the marks 010, 011, 012, 013 indicate the centers of rotation of robot arms 341 of the wafer transfer robot 34 located on the front face of the cassette 52 on the respective wafer mounting bases 31(1), 31(2), 31(3), and 31(4).

Also, the marks 014, 015 indicate the centers of rotation of the robot arms 341 of the wafer transfer robot 34 which is located in position at the front face of the respective wafer standby chambers 12(1) and 12(2).

The marks T1, T2, T3 and T4 indicate the movement tracks of the centers of the wafers 51 when accessing the wafer standby chambers 12(1), 12(2) and the reaction chambers 11(1) and 11(2) respectively by means of the wafer transfer robot 15. Likewise, T5, T6, T7, T8, T9 and T10 indicate the movement track of the center of the wafer 51 when accessing the wafer standby chambers 12(1), 12(2) and the cassette 52 respectively by means of the wafer transfer robot 34. Also, the mark T11 indicates the center of rotation of the robot arm 341 of the wafer transfer robot 34 when moving the robot arm 34 by means of the moveable base 40.

### [1-2] Operation of the Substrate Processing Apparatus

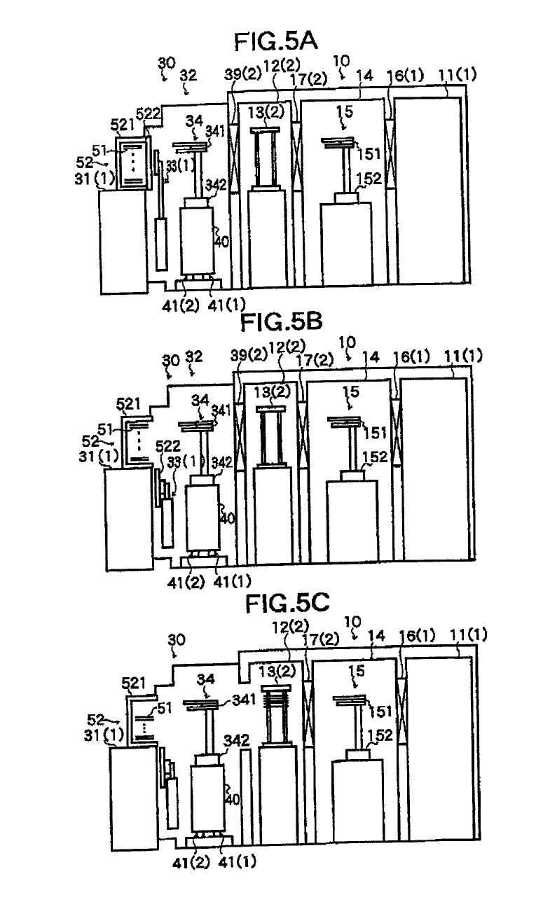

In the above construction, an example of the operation of the substrate processing apparatus according to this embodiment will now be described. First of all, the operation that the wafer 51 is transferred into the wafer standby chambers 12(1), 12(2) from the cassette 52, will be described with reference to FIGS. 5A, 5B and 5C. FIGS. 5A, 5B and 5C are views showing the sequence of this operation.

When deposition processing of the wafer 51 is performed, first of all, as shown in FIG. 5A, the cassette 52 accommodating the wafer 51 on which the film is to be deposited is mounted on the cassette mounting bases 31(1), 31(2), 31(3), 31(4). Next, the doors 325(1), 325(2), 325(3), and 325(4) of the opening/closing mechanism accommodating parts 321(1), 321(2), 321(3) and 321(4) are opened. At this point, the wafer introduction/removal ports of the opening/closing mechanism accommodating parts 321(1), 321(2), 321(3) and 321(4) are blocked by the front of the cassette 52. Sealing of the wafer transfer chamber 32 Is thereby maintained.

After this, the interior of the wafer transfer chamber 32 is evacuated to vacuum by means of the vacuum evacuation line 35 shown in FIG. 1. Also, inert gas is supplied into the interior of the wafer transfer chamber 32 by the inert gas supply line 36. In parallel with this, the oxygen concentration of the wafer transfer chamber 32 is detected by the oxygen concentration meter 37. These detection results are supplied to the control part 38. The control part 38 controls the gas supply operation of the inert gas supply line 26 In accordance with these detection results. In this way, when the detected oxygen concentration exceeds the prescribed value, the operation of supply of inert gas is executed, and when it is less than the prescribed value, this operation is stopped.

As shown in FIG. 5B, when the oxygen concentration of the wafer transfer chamber 32 is less than the prescribed value, the cover 522 of the cassette 52 is opened by the cover opening/closing mechanisms 33(1), 33(2), 33(3), 33(4). Next, as shown in FIG. 5C, the wafer 51 accommodated in the wafer accommodating part 521 of the cassette 52 is transferred to the wafer standby chambers 12(1), 12(2) by means of the wafer transfer robot 34. This transfer processing is performed for example as follows.

Specifically, in this transfer processing, first of all, the moveable base 40 is moved towards the side of the cassette mounting base 31(1) (direction X11 shown in FIG. 4). The wafer transfer robot 34 is thereby located in position at the front face of the cassette 52 on the wafer mounting base 31(1). Next, the robot arm 341 is driven in extension into the interior of the cassette 52 (direction X9 shown in FIG. 4). The tip of the robot arm 341 is thereby for example located in position directly below the uppermost wafer 51 of the plurality of wafers 51 accommodated in the cassette 52.

Next, the robot arm 341 is driven so that it is raised. The wafer 51 is thereby held at its tip. Next, the robot arm 341 is driven to perform retraction towards the outside of the cassette 52 (direction X10 shown in FIG. 4). The wafer 51 is thereby extracted from the cassette 52. Next, after the robot arm 341 has been driven in rotation by about 180°, the moveable base 40 is moved towards the wafer standby chambers 12(1), 12(2). The wafer transfer robot 34 is thereby located in position at the front face of the wafer standby chamber 12(1).

Next, after the gate valve 39(1) has been opened, the robot arm 341 is driven in extension Into the interior of the wafer standby chamber 12(1) (direction X10 shown in FIG. 4). The wafer 51 is thereby inserted into the interior of the wafer standby chamber 12(1). Next, the robot arm is driven so as to lower it. The wafer 51 is thereby mounted on the wafer mounting shelf 13(1). Next, the robot arm is driven so as to retract it towards the outside of the wafer standby chamber 12(1) (direction X9 shown in FIG. 4), and is then driven in rotation by about 180°.

Transfer processing of the uppermost wafer 51 is thereby completed. Subsequently in the same way, transfer processing as described above is executed in respect of the second and third, . . . wafers 51 from the top. Then, when transfer processing of all the wafers 51 accommodated in the cassette 52 on the wafer mounting base 33(1) has been completed, transfer processing of the wafers 51 accommodated In the cassette 52 on the next wafer mounting base 33(2) is executed.

Thereafter in the same way, processing as described above is repeated until transfer processing of wafers 51 accommodated in the cassette 52 on the last wafer mounting base 33(4) has been completed. In this case, when the wafer mounting shelf 13(1) becomes full, the gate valve 39(1) is closed and the gate valve the 39(2) is opened. Wafer transfer processing into the wafer standby chamber 12(2) Is now thereby performed.

When this water transfer processing is completed, wafer transfer processing into the reaction chambers 11(1) and 11(2) from the wafer standby chambers 12(1) and 12(2) is performed.

Next, this wafer transfer processing will be described with reference to FIG. 1 etc. This wafer transfer processing is performed in practically the same war as the wafer transfer processing into the wafer standby chambers 12(1) and 12(2) from the cassette 52.

Specifically, in this wafer transfer processing, first of all, the gate valve 17(1) shown in FIG. 1 is opened. Next, the robot arm 151 of the wafer transfer robot 15 is driven in extension into the interior of the wafer standby chamber 12(1) (direction X5 shown in FIG. 4). The tip of the robot arm 151 is thereby for example located In position directly below the uppermost water 51 of the plurality of wafers 51 mounted on the wafer mounting shelf 13(1).

Next, drive to raise the robot arm 151 is performed. The wafer 51 is thereby held at the tip of the robot arm 151. Next, the robot arm 151 is driven in retraction towards the outside of the wafer standby chamber 12(1) (direction X6 shown in FIG. 4). The uppermost wafer 52 is thereby extracted from the wafer standby chamber 12(1).

Next, the robot arm 151 is driven in rotation and is then driven in extension into the interior of the reaction chamber 11(1) (direction X1 shown in FIG. 4). The wafer 51 that is held at the tip of the robot arm 151 is thereby transferred into the reaction chamber 11(1). Next, the robot arm 151 is driven so as to lower it. The wafer 51 is thereby mounted In the mounting part of the reaction chamber 11(1).

Next, the robot arm 151 is driven in retraction to outside the reaction chamber 11(1) (direction X2 shown in FIG. 4), after which the gate valve 16(1) is closed. Transfer processing of the uppermost wafer 51 into the reaction chamber 11(1) from the wafer standby chamber 12(1) is thereby completed.

When this transfer processing is completed, transfer processing of the uppermost wafer 51 into the reaction chamber 11(2) from the wafer standby chamber 12(2) is executed. This transfer processing is also performed in the same way as the transfer processing of wafers 51 from the wafer standby chamber 12(1) into the reaction chamber 11(1).

When transfer processing of the wafer 51 from the wafer standby chambers 12(1) and 12(2) into reaction chambers 11(1) and 11(2) is completed, deposition processing onto this wafer 51 is executed. When this deposition processing is completed, the wafer 51 that has been subjected to deposition processing is transferred into the wafer standby chambers 12(1) and 12(2). This transfer processing is performed in the opposite sequence to the wafer transfer processing into reaction chambers 11(1) and 11(2).

When this transfer processing has been completed, the processing described above is executed in respect of the wafer 51 that is second from the top of the plurality of wafers 51 accommodated in the wafer standby chambers 12(1) and 12(2). Subsequently. in the same way, the processing described above is executed in respect of the third, fourth and . . . wafers 51 from the top.

When transfer processing of all the wafers 51 has been completed, processing to transfer the wafers 51 that have been subjected to deposition from the wafer standby chambers 12(1) and 12(2) into the cassette 52 is executed. This transfer processing Is performed by the opposite sequence to the wafer transfer processing from the cassette 52 into the wafer standby chambers 12(1) and 12(2).

When all the wafers 51 that have been subjected to deposition processing have been returned to the cassette 52, the wafer introduction/removal port of the wafer accommodating part 521 of the cassette 52 is blocked by the cover 522 as shown in FIG. 5A. After this, the cassette 52 is transferred to the next wafer processing apparatus by means of a cassette transfer apparatus, not shown. Also, the wafer introduction/removal ports of the opening/closing mechanism accommodating parts 321(1), 321(2), 321(3), and 321(4) are closed by the doors 325(1), 325(2), 325(3), and 325(4). After this, processing as described above is again executed in respect of the wafers 51 accommodated in the next four cassettes 52.

The above is one example of the operation of a substrate processing apparatus according to this embodiment. In the above description, the case was described in which the wafer transfer processing from cassette 52 to wafer standby chambers 12(1), 12(2), deposition processing and wafer transfer processing from the wafer standby chambers 12(1), 12(2) to the cassette 52 were performed sequentially.

However, in this embodiment, these could be performed in parallel. This is because, in this embodiment, the wafer mounting shelves 13(1), 13(2) that hold the wafers 51 are provided in the wafer standby chambers 12(1), 12(2). Also, it is because these wafer mounting shelves 13(1), 13(2) hold a plurality of wafers 51.

That is, with such a construction, the wafer mounting shelves 13(1), 13(2) constitute a buffer mechanism between the wafer transfer processing on the transfer part side and the wafer transfer processing on the processing part side. “Wafer transfer processing on the transfer part side” means wafer transfer processing between the cassette 52 and the wafer standby chambers 12(1), 12(2). Also “wafer transfer processing on the processing part side” means wafer transfer processing between the wafer standby chambers 12(1), 12(2) and reaction chambers 11(1), 11(2).

The water transfer processing from the cassette 52 to the wafer standby chambers 12(1), 12(2) and the wafer transfer processing from the wafer standby chambers 12(1), 12(2) to the reaction chambers 11(1), 11(2) can thereby be performed independently. Also, the wafer transfer processing from the reaction chambers 11(1), 11(2) to the wafer standby chambers 12(1), 12(2) and the wafer transfer processing from the wafer standby chambers 12(1), 12(2) to the cassette 52 can also be performed independently.

As a result, the wafer transfer processing from the cassette 52 to the wafer standby chambers 12(1), 12(2), the deposition processing, and wafer transfer processing from the wafer standby chambers 12(1), 12(2) to the cassette 52 can be performed in parallel.

### [1-3] Construction of the Wafer Mounting Shelves 13(1), 13(2)

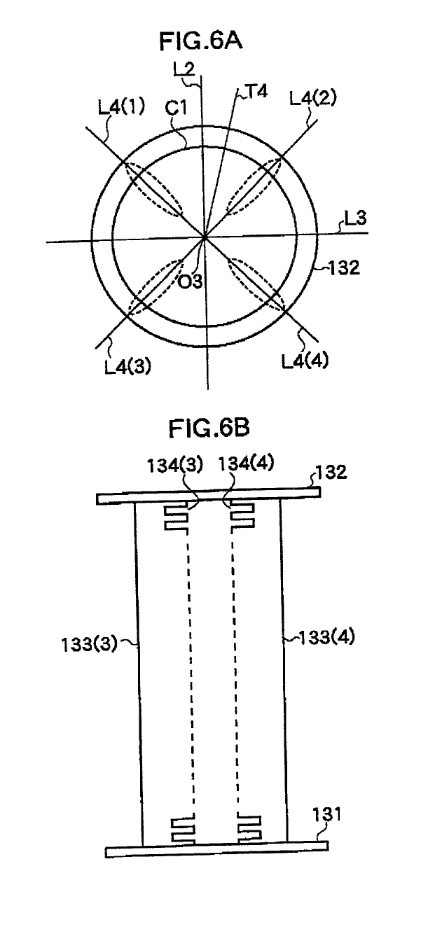

Next, the construction of the wafer standby shelves 13(1), 13(2) will be described. These have practically identical constructions. Consequently, In the description below, the construction of the wafer mounting shelf 13(1) will be described as a representative example. FIGS. 6A and 6B are views showing the construction of this wafer mounting shelf 13(1).

FIG. 6A is a plan view seen from above of the wafer mounting shelf 13(1) and FIG. 6B is a side view seen from the side. As shown in the drawing, the wafer mounting shelf 13(1) comprises a bottom plate 131. a ceiling plate 132, and four support pillars 133(1), 133(2), 133(3) and 133(4).

The bottom plate 131 and the ceiling plate 132 are for example formed as disc shapes. The support pillars 133(1), 133(2), 133(3) and 133(4) are for example formed in elongate plate shape. Also, the cross parts of these support pillars 133(1), 133(2), 133(3) and 133(4) are for example formed in an elongate elliptical shape. Furthermore, the lengths of these support pillars 133(1), 133(2), 133(3) and 133(4) are set to the same length.

In such a construction, the support pillars 133(1), 133(2), 133(3), and 133(4) are erected perpendicularly on the base plate 131. The ceiling plate 132 is supported at the top ends of the support pillars 133(1), 133(2), 133(3) and 133(4).

In this case, the support pillars 133(1), 133(2), 133(3) and 133(4) are mounted in the shape of a circle C1 centered on the center of the ceiling plate 132. The center of the ceiling plate 132 coincides with the center 03 of the wafer 51 mounted on the wafer mounting shelf 13(1). Consequently, in the description below, the center of the ceiling plate 132 Will be denoted as 03.

Also, the support pillars 133(1) and 133(2) are arranged with axial symmetry with respect to the center line L2 of the ceiling plate 132. The center line L2 is a center line passing through the center 03 of the ceiling plate 132 and extending in the direction X9-X10 shown in FIG. 4. Likewise, the support pillars 133(3) and 133(4) are also arranged axially symmetrically with the respect to the center line L2. Also, the support pillars 133(1), 133(3) are arranged axially symmetrically with respect to the center line L3, which is perpendicular to the center line L2. Likewise, the support pillars 133(2). 133(4) are also arranged axially symmetrically with respect to the center line L3.

In this way, the support pillars 133(1) and 133(4) are arranged point-symmetrically with respect to the center 03 of the ceiling plate 132. Likewise, the support pillars 133(2), and 133(3) are arranged point-symmetrically with respect to center 03.

Also, the support pillars 133(1), 133(2), 133(3) and 133(4) are set such that the extension lines of their major axes (hereinbelow called “major axes”) L4(1), L4 (2), L4(3), and L4(4) pass through the center 03 of the ceiling plate 132. In this case, the support pillars 133(1), 133(4) are arranged point-symmetrically with respect to the center 03, so the major axes L4(1) and L4(4) coincide, Likewise, the major axes L4(2) and L4(3) also coincide.

A plurality of grooves 134(n)(n=1,2,3,4) into which the peripheries of wafers 51 are inserted are formed in each of the support pillars 133(n). This plurality of grooves 134(n) are respectively horizontally formed. That is, their depth directions are formed so as to be directed in the horizontal direction. Also, this plurality of grooves 134(n) are arranged in the vertical direction.

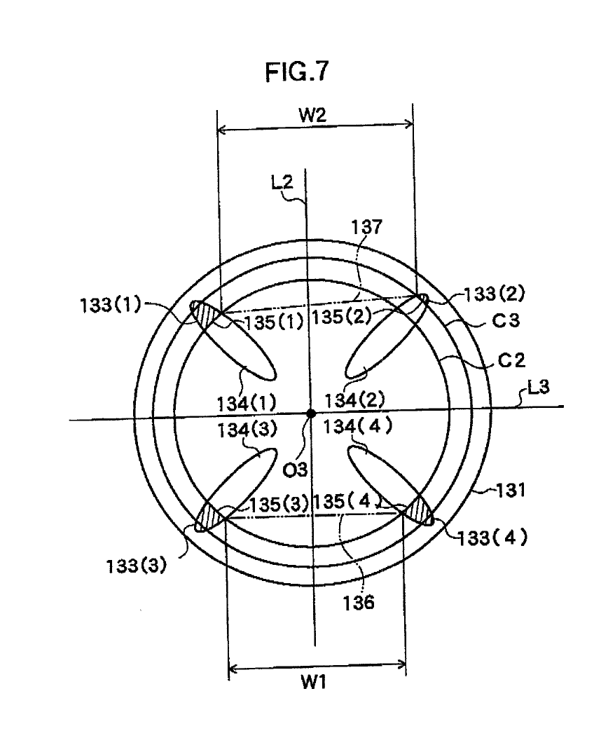

FIG. 7 is a cross-sectional view showing the case where the support pillars 133(1), 133(2), 133(3) and 133(4) are sectioned horizontally.

As shown in the drawings, the grooves 134(1), 134(2), 134(3) and 134(4) are formed so as to be directed outwards from the center 03 of the ceiling plate 132. In this case. the bottom faces 135(1), 135(3), and 135(4) of the grooves 134(1), 134(3), 134(4) excluding the groove 134(2) are set so as to be positioned on a circle C2 centered on the center 03 of the ceiling plate 132. In contrast, the bottom face 135(2) of the groove 134(2) is set so as to be positioned on the circle C3 centered on the center 03 of the ceiling plate 132.

The diameter of the circle C3 is set so as to be larger than the diameter of the circle of C2. The groove 134(2) is thereby set so as to be deeper than the grooves 134(1), 134(3), and 134(4).

In this construction, the gap between the support pillars of 133(3) and 133(4) is employed as a wafer introduction/removal port (hereinbelow called “transfer part side wafer introduction/removal port”) which is accessed by the wafer transfer robot 34 shown in FIG. 1. Also, the gap between the support pillars 133(1), 133(2) is employed as a wafer introduction/removal port (hereinbelow called “processing part side wafer introduction/removal port”) 137 that is accessed by the wafer transfer robot 15 shown in FIG. 1.

In this case, the support pillars 133(3) and 133(4) are arranged axially symmetrically with respect to a straight line L2. In this way, the transfer part side wafer introduction/removal port 136 faces the direction of access of the wafer mounting shelf 13(1) by the wafer transfer robot 34. The wafer mounting shelf 12(1) can thus be accessed by the wafer transfer robot 34

In contrast, the support pillars 133(1) and 133(2) are arranged axially symmetrically with respect to the straight line L2, The processing part side wafer introduction/removal port 137 therefore faces a different direction from the direction of access of the wafer mounting shelf 13(1) by the wafer transfer robot 15. As a result, the wafer standby chamber 13(1) cannot be accessed by the wafer transfer robot 15.

However, in this embodiment, the depth of the groove 134(2) is set to be deeper than the depth of grooves 134(1), 134(3), and 134(4). The position of the processing side wafer introduction/removal port 137 is thereby displaced towards the support pillar 133(2) from the center line L2. As a result, even though the processing side wafer introduction/removal port 137 is facing a direction different from the direction of access of the wafer mounting shelf 13(1) by the wafer transfer robot 15, the wafer standby chamber 13(1) can be accessed by the wafer transfer robot 15.

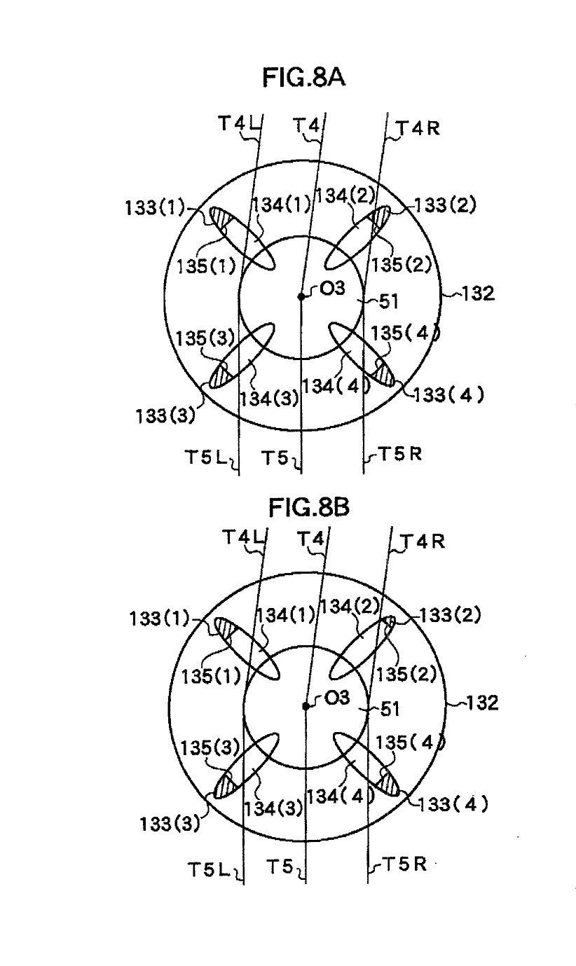

This is described using FIGS. 8A and 8B. FIG. 8A shows the case where the depth of the groove 134(2) is the same as the depth of the grooves 134(1), 134(3), 134(4); FIG. 8B shows the case where the depth of the groove 134(2) is deeper than the depth of the grooves 134(1), 134(3), 134(4).

In FIG. 8A and 8B, T5 indicates the movement track of the canter of the wafer 51 when the wafer mounting shelf 13(1) is accessed by the wafer transfer robot 34 as described above. The marks T5L and T5R likewise show the movement tracks of the periphery of the wafer 51. In contrast, The marks 74 shows the movement track of the center of the wafer 51 when the wafer mounting shelf 13(1) is accessed by the wafer transfer robot 15 as described above. The marks T4L and T4R likewise show the movement tracks of the periphery of the wafer 51.

In the case of FIG. 8A, the movement track T4R of the wafer 51 overlaps with the support pillar 133(2). In this case, therefore, the periphery of the wafer 51 collides with the support pillar 133(2). As a result, in this case, access of the wafer mounting shelf 13(1) by the wafer transfer robot 15 is impossible.

In contrast, in the case of FIG. 8B, the movement track T4R of the periphery of the wafer 51 does not overlap the support pillar 133(2), In this case, therefore. the wafer mounting shelf 13(1) can be accessed by the wafer transfer robot 15.

Although a detailed description will be omitted, the wafer mounting shelf 13(2) is also constructed practically Identically with the wafer mounting shelf 13(1). However, in this case, the depth of the groove 134(1) of the support pillar 133(1) is set to be deeper than the depth of the grooves 134(2), 134(3), 134(4) of the other support pillars 133(2), 133(3) and 133(4).

### [1-4] Benefit

With this embodiment as described in detail above, the following benefits can be obtained.

(1) First of all, according to this embodiment, when the wafer 51 is transferred between the wafer deposition part 10 and the cassette 52 on the cassette mounting bases 31(1), 31(2), 31(3), 31(4) shown in FIG. 1, the wafer 51 is transferred through a sealed space that is cleansed by inert gas. It is thereby possible to prevent the wafer 51 from being contaminated by a natural oxide film etc whilst it is being transferred within the apparatus. As a result, it becomes possible to deal with demands for increased density of semiconductor wafer integration in the future.

(2) Also, according to this embodiment, thanks to the provision of a sealed space that is cleansed by inert gas between the cassette mounting bases 31(1), 31(2), 31(3), 31(4) and the wafer deposition part 10, contamination as aforesaid is prevented. This makes it possible to use practically all existing CVD apparatuses without modification.

(3) Also, according to this embodiment, the wafer holding parts (the wafer mounting shelves 13(1), 13(2)) are provided in the wafer standby chambers 12(1), 12(2). In this way, the transfer part side wafer transfer processing and the processing part side wafer transfer processing can be coupled by a buffer mechanism. As a result, independence of the two transfer processes can be achieved. The throughput of the CVD apparatuses can thereby been raised.

(4) Also, according to this embodiment, the wafer mounting shelves 13(1), 13(2) are employed as substrate holding parts. The substrate holding part can thereby be constructed In a simple fashion.

(5) Also, according to this embodiment, as the wafer mounting shelves, the wafer mounting shelves 13(1), 13(2) that are capable of holding a plurality of wafers 51 are employed as shown in FIG. 68. In this way, the wafers 51 that are transferred by the wafer transfer robots 15, 34 can be held simultaneously. That is, the wafers 51 that are transferred by another wafer transfer robot 34 or 15 can be held in a condition in which the wafers 51 transferred by one wafer transfer robot 15 or 34 are held. As a result, the independence of the transfer part side wafer transfer processing and processing part side wafer transfer processing can be improved compared with the case in which a single wafer 51 can be held.

(6) Also, according to this embodiment, the wafer mounting shelves 13(1), 13(2) having a transfer part side wafer introduction/removal port 136 and processing part side wafer introduction/removal port 137 can be employed as the wafer mounting shelves as shown in FIG. 7. In this way, even if access to the wafer mounting shelves 13(1), 13(2) by the wafer transfer robots 15, 34 occurs simultaneously, adjustment of conflict thereof is not required. As a result, the throughput of the CVD apparatuses can be improved.

(7) Also, in this embodiment, the position of the processing part side wafer introduction/removal port 137 of the wafer mounting shelves 13(1), 13(2) is offset towards the movement track T4 of the wafer 51 by the wafer transfer robot 15. The difference of access direction of the wafer mounting shelves 13(1), 13(2) by the wafer transfer robots 15, 34 can therefore be absorbed by a simple construction.

(8) Also, in this embodiment, by making the depth of the groove 134(2) deeper than the depth of the other groups 134(1), 134(3), 134(4), the position of processing part side wafer introduction/removal port 137 is offset towards the movement track T4. In this way, the position of the processing part side wafer introduction/removal port 137 can be offset by a brief construction.

(9) Also, in this embodiment, when the interior of the transfer part side wafer transfer chamber 32 is cleansed by inert gas, supply processing of inert gas is conducted only when the oxygen concentration exceeds a prescribed value. In this way, the quantity of inert gas used can be reduced.

### [2] Second Embodiment

### [2-1] Construction

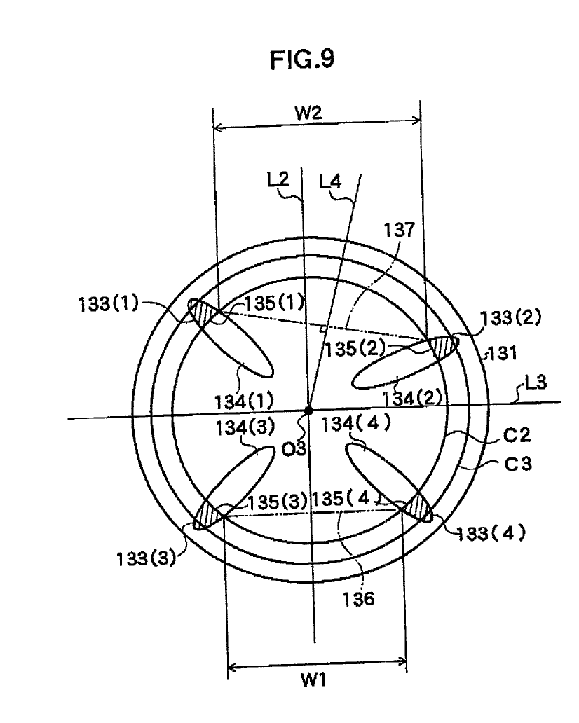

FIG. 9 is a view showing the construction of major parts of a second embodiment of the present invention. In FIG. 9, parts that perform practically the same function as in FIG. 7 described above are given the same reference symbols.

In the embodiment described above, the case was described in which the difference in direction of access of the wafer mounting shelves 13(1), 13(2) depending on the wafer transfer robots 15, 34 was absorbed by suitably setting the positions of the wafer introduction/removal ports 136, 137. In contrast, in this embodiment, the difference in direction of access of the wafer mounting shelves 13(1), 13(2) depending on the wafer transfer robots 15, 34 is absorbed by suitably setting the orientations of the wafer introduction/removal ports 136, 137.

In order to implement this, in this embodiment, as shown in FIG. 9, the position of the support pillar 133(2) is offset towards the support pillar 133(4). However. in this case, in contrast to the previous embodiment, the depth of groove 134(2) of the support pillar 133(2) is set to be the same as the depth of the grooves 134(1), 134(2), 134(4) of the other support pillars 133(1), 133(3), and 133(4).

FIG. 9 shows a typical example of the construction of the wafer mounting shelf 13(1). In the case of the wafer mounting shelf 13(2), the support pillar 133(1) is offset towards the support pillar 133(3).

### [2-2] Benefits

(1) In this embodiment, the processing part side wafer introduction/removal port 137 is directed in the direction of access of the wafer mounting shelves 13(1), 13(2) by the wafer transfer robot 15. In this way, in the same way as in the embodiment previously described, the difference in direction of access of the wafer mounting shelves 13(1), 13(2) depending on the wafer transfer robot 15 or 34 can be absorbed by a brief construction.

(2) Also. in this embodiment, the orientation of the wafer introduction/removal ports 136, 137 is suitably set by suitably setting the position of arrangement of the support pillars 133(1), 133(2), 133(3), 133(4). In this way, the orientations of the wafer introduction/removal ports 136, 137 can be suitably set by a brief construction.

### [3] Third Embodiment

### [3-1] Construction

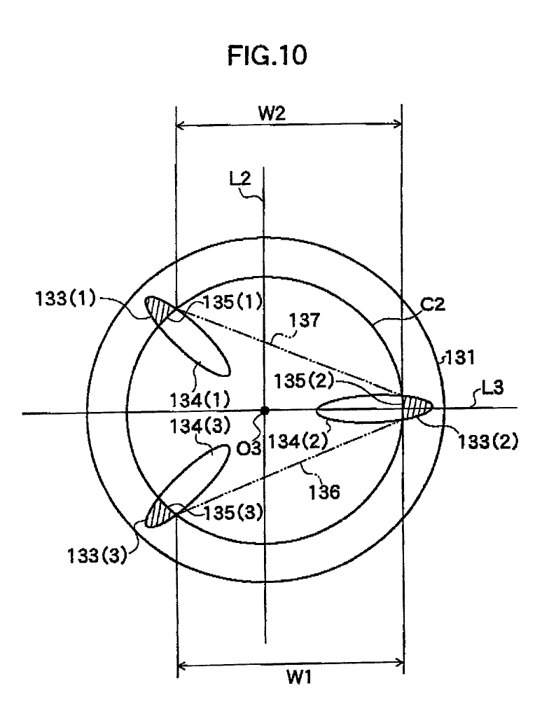

FIG. 10 is a view showing the construction of major parts of a third embodiment of the present invention. In FIG. 10, parts which have practically the same function as in FIG. 7 are given the same reference. symbols.

In the previous embodiments, the case was described in which the difference in direction of access of the wafer mounting shelves 13(1), 13(2) dependent on the wafer transfer robot 15 or 34 was absorbed by suitably setting the position or orientation of the wafer introduction/removal ports 136, 137. In contrast, in this embodiment, the difference in direction of access of the wafer mounting shelves 13(1), 13(2) dependent on the wafer transfer robot 15 or 34 is absorbed by suitably setting the width of the wafer introduction/removal ports 136, 137.

In order to implement this, in this embodiment, as shown in FIG. 10, the support pillar 133(2) and the support pillar 133(4) are integrated. In FIG. 10, the reference symbol 133(2) is affixed to an integrated support pillar. In this case, the support pillar 133(2) is for example arranged on a straight line L3.

FIG. 10 shows a typical example of the construction of the wafer mounting shelf 13(1). In the case of the wafer mounting shelf 13(2), the support pillar 133(1) is integrated with the support pillar 133(3).

### [3-2] Benefits

(1) In this embodiment, the processing part side wafer introduction/removal port 137 was directed in a direction different from the direction of access of the wafer mounting shelves 13(1), 13(2) by the wafer transfer robot 15. However, in this case, the width W2 of the processing part side wafer introduction/removal port 137 is expanded. In this way, by a brief construction, in the same way as in the case of the previously described embodiments, the difference in direction of access of the wafer mounting shelves 13(1), 13(2) depending on the wafer transfer robots 15 or 34 can be adsorbed. This applies in the same way In respect of the transfer part side wafer introduction/removal port 136.

(2) Also, in this embodiment, the width of the wafer introduction/removal ports 136, 137 is suitably set by suitably setting the position of arrangement of the support pillars 133(1), 133(2), 133(3). In this way, the width of the wafer introduction/removal ports 136, 107 can be suitably set by means of a brief construction.

Furthermore, in the above-mentioned first, second and third embodiment, the case was described in which the difference of the access directions of the wafer mounting shelves 13(1), 13(2) dependent on the wafer transfer robot 15, 34 was absorbed by suitably setting of any one of the positions, orientations and widths of the wafer introduction/ removal ports 136,137. However, in the present invention, it would also be possible to absorb the difference of the access directions by suitably setting of two or three of them.

### [4] Fourth Embodiment

### [4-1] Construction

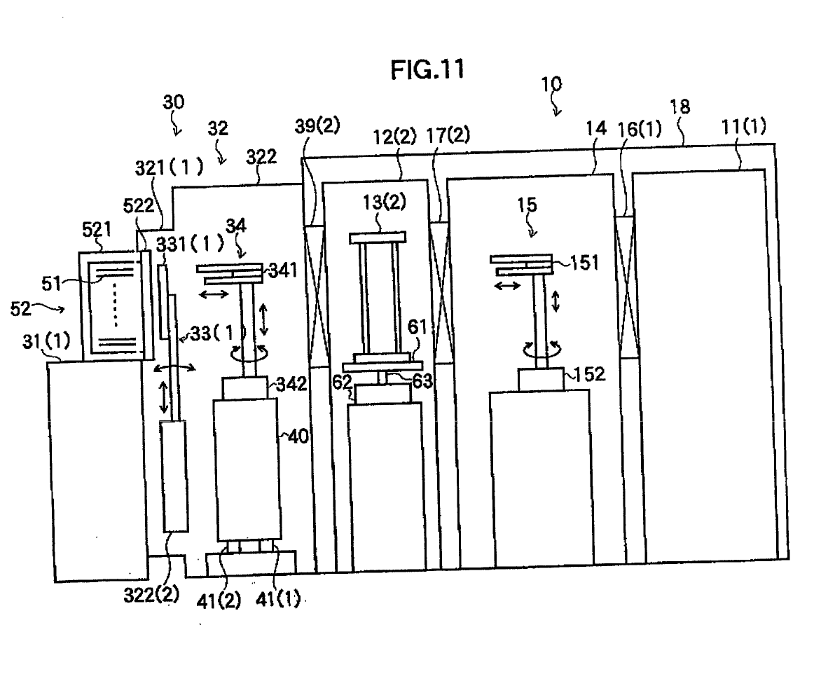

FIG. 11 is a view showing the construction of major parts of a fourth embodiment of the present invention. In FIG. 11, parts that have practically the same function as in the case of previous FIG. 2 are given the same reference symbols.

In the first to third embodiments above, the cases were described in which the difference in direction of access of the wafer mounting shelves 13(1), 13(2) dependent on the wafer transfer robots 15. 34 was absorbed by suitably setting the position, orientation, or width of the wafer introduction/removal ports 136, 137. In contrast, In this embodiment, this difference is absorbed by driving the wafer mounting shelves 13(1), 13(2) in rotation.

In order to implement this, in this embodiment, as shown in FIG. 11, the wafer mounting shelves 13(1), 13(2) are mounted on a rotary plate 61. This rotary plate 61 is driven in rotation about a rotary shaft 63 by a rotary drive part 62. This rotary shaft 63 is set up to extend in the vertical direction. Also, this rotary shaft 63 is set up so as to pass through the center 03 of the ceiling plate 132.

### [4-2] Action

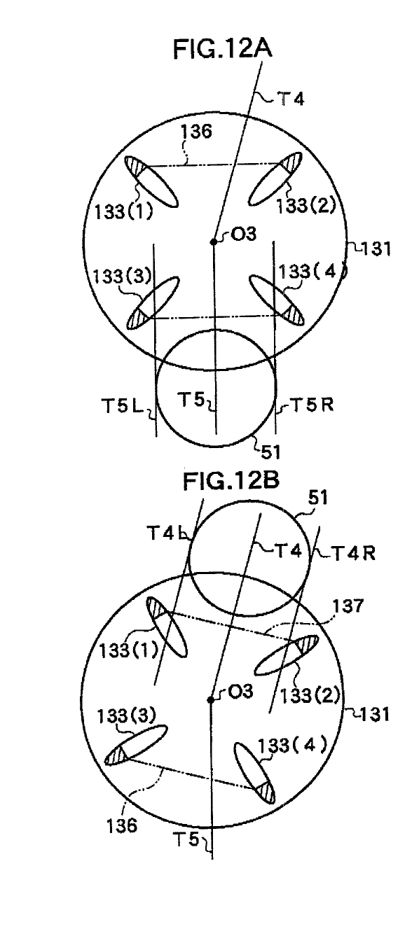

With this arrangement, when accessing the wafer mounting shelves 13(3), 13(2) by means of the wafer transfer robot 34, these wafer mounting shelves 13(1), 13(2) are driven in rotation as shown in FIG. 12A such that the transfer part side wafer introduction/removal port 136 faces the direction of access by the wafer transfer robot 34.

In contrast, when performing access by means of the wafer transfer robot 15, the wafer mounting shelves 13(1), 13(2) are driven in rotation as shown in FIG. 12(b) such that the processing part side wafer introduction/removal port 137 faces the direction of access by the wafer transfer robot 15. FIGS. 12A and 12B show as a typical example the case of access of the wafer mounting shelf 13(1).

### [4-3] Benefits

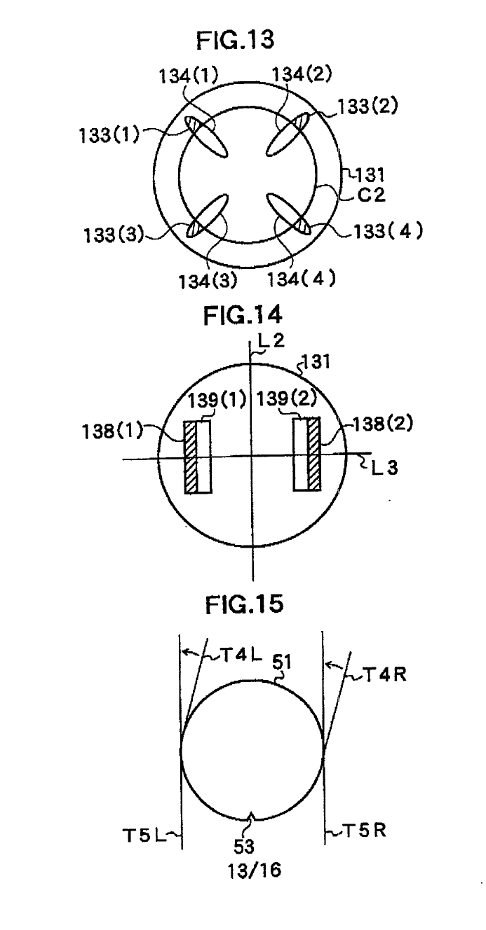

(1) In this embodiment, the wafer mounting shelves such as would be used if the direction of access by the wafer transfer robots 15, 34 were the same can be used as the wafer mounting shelves 13(1), 13(2). In this way, as shown in FIG. 13, the shapes of the support pillars 133(1), 133(2), 133(3), 133(4) (depth of grooves 134(1), 134(2), 134(3), 134(4) etc.) can be standardized. Also, the support pillars 133(1), 133(2), 133(3), 133(4) can be symmetrically arranged. As a result, the wafer mounting shelves 13(1), 13(2) can be manufactured in a brief fashion.

(2) Also, with this construction, as shown in FIG. 14, the wafer mounting shelves having two plate-shaped support pillars 138(1), 138(2) can be employed as the wafer mounting shelves 13(1), 13(2). The wafer 51 can thereby be held in a stable fashion.

The support pillars 138(1), 138(2) are arranged parallel and axially symmetrically with respect to the center line L2. Also, the support pillars 138(1), 138(2) are arranged on the center line L3. Also, the grooves 139(1), 139(2) for holding the wafer 51 are formed along the center line L2.

(3) Also, in this embodiment, as shown in FIG. 15, as a result, the access directions of the wafer mounting shelves 13(1), 13(2) by the wafer transfer robots 15, 34 can be aligned. In this way, the crystal orientation of the wafer 51 in the reaction chambers 11(1), 11(2) can be set to a desired orientation. As a result, deposition characteristics can be improved compared with a case in which this crystal orientation is offset from the desired orientation.

That is, the wafer 51 has a crystal orientation. If this crystal orientation is offset from the desired orientation, when deposition processing is performed at a high temperature within the reaction chambers 11(1), 11(2), warping of the wafer 51 may occur. When this warping occurs, the deposition characteristics of the wafer 51 may be impaired compared with no warping occurring. Accordingly, when deposition processing of the wafer 51 is performed, it is desirable to align this crystal orientation with the desired orientation.

However, In the first to third embodiments described above, it was not possible to align the access directions of the wafer mounting shelves 13(1), 13(2) by the wafer transfer robots 15, 34. Consequently, in these embodiments, it was not possible to set the crystal orientation of the wafer 51 transferred into the reaction chambers 11(1), 11(2) in a desired orientation.

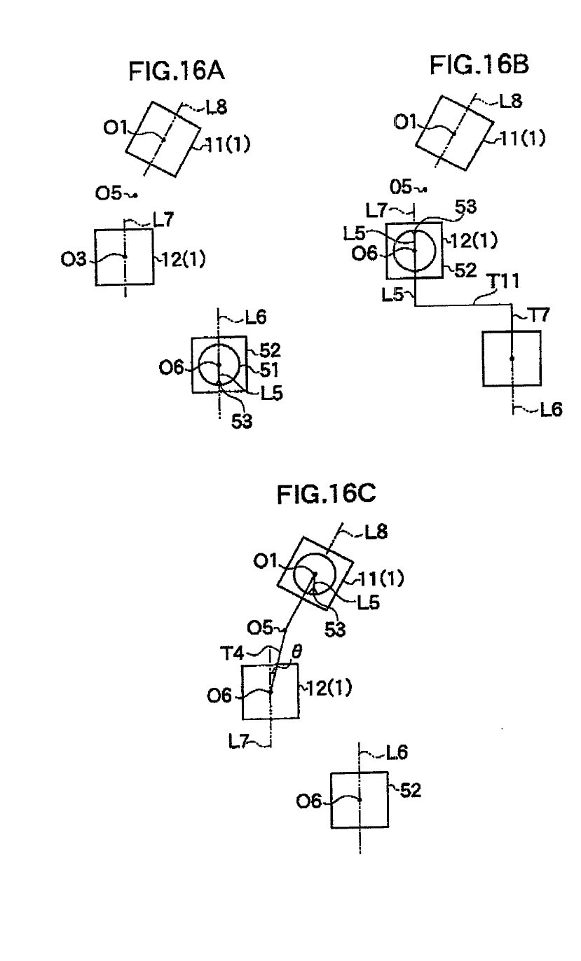

FIGS. 16A, 16B and 16C are views showing this. In this Figure, the wafer standby chamber 12(1) and the reaction chamber 11(1) are illustrated as typical examples of a wafer standby chamber and reaction chamber.

In the Figure, 53 indicates a cut-away portion called a notch or orientation flat. This cut-away portion 53 is formed on the wafer 51 in order to indicate the crystal orientation of the wafer 51. The mark L5 indicates the diameter of the water 51 passing through the cut-away portion 53. Also, the marks L6, L7 and L8 respectively indicate the center lines of the cassette 52, the wafer standby chamber 12(1), and the reaction chamber 11(1). These center lines L6, L7, L8 pass through the centers 06, 03, 01 of wafers 51 accommodated in the cassette 52, the wafer standby chamber 12(1), and the reaction chamber 11(1), being lines bisecting the cassette 52, the wafer standby chamber 12(1), and the reaction chamber 11(1).

FIG. 16A shows the condition in which the wafer 51 is accommodated in the cassette 52; FIG. 16B shows the condition in which the wafer 51 has been transferred into the wafer standby chamber 12(1); and FIG. 16(c) shows the condition in which the wafer 51 has been transferred into the reaction chamber 11(1).

Let us now assume that the crystal orientation of the wafer 51 in the reaction chamber 11(1) is set in a orientation such that its diameter L5 is along the center line L8 of the reaction chamber 11(1). Also let us assume that the wafer 51 is accommodated with respect to the cassette 52 as shown in FIG. 16A such that its diameter L5 is along the center line L6.

At this point, the excess angles of the cassette 52 and the wafer standby chamber 12(1) by the wafer transfer robot 34 are the same. In the example Illustrated, this access angle is 90°. The diameter L5 of the wafer 51 that has been transferred into the wafer standby chamber 12(1) is therefore along the center line L7 of the wafer standby chamber 12(1) as shown in FIG. 16B.

However, the access directions of the wafer standby chamber 12(1) by the wafer transfer robots 15, 34 are different. As a result, as shown in FIG. 16C, the diameter L5 of the wafer 51 transferred into the reaction chamber 11 is inclined with respect to the center line L8 thereof, The angle of this inclination is equal to the angle θ of inclination of the access direction of the wafer transfer robot 15 with the respect to the center line L7 of the wafer standby chamber 12(1). As a result, the crystal orientation of the wafer 51 in the reaction chamber 11(1) is offset from the desired orientation. Warping of the wafer 51 is thereby generated. As a result, the deposition characteristics may impair compared with no warping occurs.

In order to solve this problem, for example the following four arrangements(A),(B),(C) and (D) may be considered:

(A) arrangement wherein when the wafer 51 is transferred into the wafer standby chamber 12(1) by the wafer transfer robot 34, it is transferred in offset in inclined fashion:

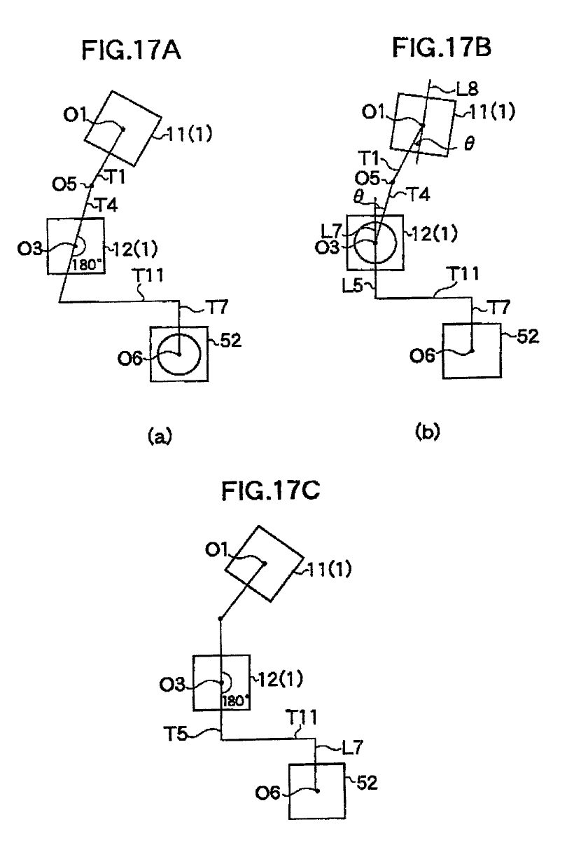

(B) arrangement wherein, as shown in FIG. 17A, the access direction of the wafer standby chamber 12(1) by the wafer transfer robot 34 is made to coincide with the access direction of the wafer standby chamber 12 of (1) by the wafer transfer robot 15;

(C) arrangement wherein, as shown in FIG. 17B, the access angle of the reaction chamber 11(1) by the wafer transfer robot 15 is made to coincide with the access angle (θ) of the wafer standby chamber 12(l) by this robot 15;

(D) arrangement wherein, as shown in FIG. 17C, the transfer direction of the wafer standby chamber 12(1) by the wafer transfer robot 15 is made to coincide with the access direction of the wafer standby chamber 12(1) by the wafer transfer robot 34.

In the case of arrangement (A), the direction of the wafer 51 in the wafer standby chamber 12(1) can be altered. In this way, the crystal orientation of the wafer 51 that is transferred Into the reaction chamber 11(1) can be aligned with a desired orientation.

However, with this arrangement, the operation of the robot arm 341 becomes complicated. As a result, control of the robot arm 341 becomes difficult Even if such control could be achieved, there would be the problems of increased manufacturing costs of the apparatus and a lowering of reliability of the apparatus.

Also, in the case of arrangement (B), the direction of access of the wafer standby chamber 12(1) by the wafer transfer robots 15, 34 can be made to coincide. In this way, the crystal orientation of the wafer 51 that is transferred into the reaction chamber 11(1) can be made to coincide with a desired orientation.

However, with this arrangement, the access angle of the cassette 52 by the wafer transfer robot 34 and the access angle of the wafer standby chamber 12(1) are different. The problem therefore arises that control of this robot 34 becomes troublesome.

In contrast, in the case of the arrangements (C) and (D), problems as in the case of the arrangements (A), or (B) do not occur. However, in the case of these arrangements, the direction of the reaction chamber 11(1) must be altered. The problem therefore arises that the existing CVD apparatus cannot be utilized.

To deal with this, in this embodiment, the wafer mounting shelf 13(1) is driven in rotation, In this way, the access directions of the wafer standby chamber 12(1) by the wafer transfer robots 15, 34 can be aligned. The crystal orientation of the wafer 51 that has been transferred into reaction chamber 11(1) by utilizing an existing CVD apparatus can therefore be aligned with a desired orientation.

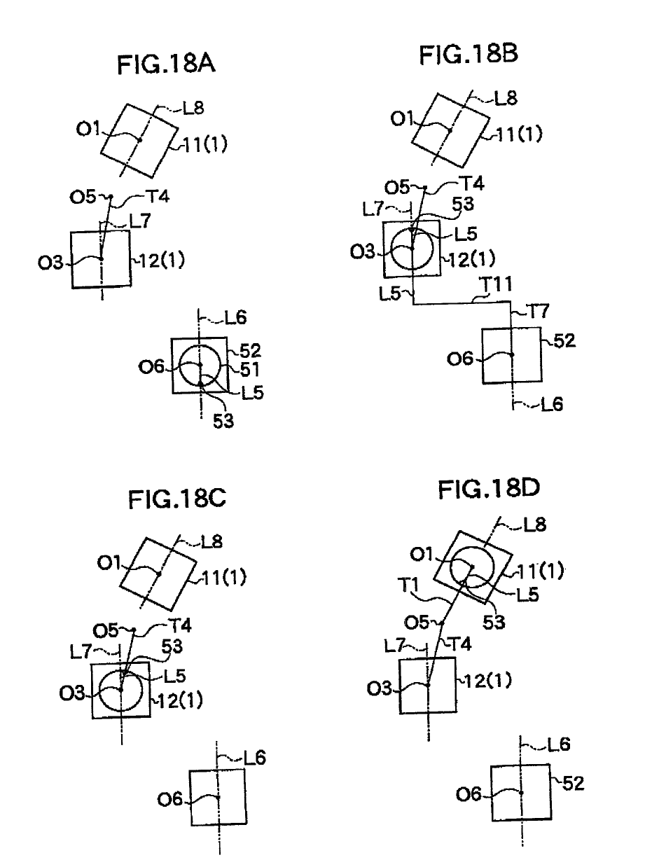

FIGS. 18A, 18B, 18C and 18D are views showing how this is done. FIG. 18A shows the condition in which the wafer 51 is accommodated in the cassette 52; FIG. 18B shows a condition in which the wafer 51 has been transferred into the wafer standby chamber 12(1); FIG. 18C shows the condition in which the wafer mounting shelf 13(1) has been driven in rotation; and FIG. 18D shows the condition in which the wafer 51 has been transferred into the reaction chamber 11(1).

As shown in FIG. 18C, in this embodiment, the diameter L5 of the wafer 51 is directed in the access direction of the wafer standby chamber 12(1) by the wafer transfer robot 15 by driving the wafer mounting base 13(1) in rotation. The diameter L5 of the wafer 51 that is transferred into the reaction chamber 11(1) is thereby aligned with the center line L8 of the reaction chamber 11(1) as shown in FIG. 18D. As a result, the crystal orientation of the wafer 51 is aligned with a desired orientation.

### [5] Other Embodiments

Although four embodiments of the present invention have been described in detail above, the present invention is not restricted to these embodiments described above.

(1) For example, in the preceding embodiments, the case was described in which the wafer mounting shelves 13(1), 13(2) capable of mounting a plurality of wafers 51 were employed as the wafer mounting shelves. However, in the present invention, it would also be possible to employ a wafer mounting shelf capable of mounting only a single wafer 51.

Even with such an arrangement, In each of wafer transfer processing from the cassette 52 towards the reaction chambers 11(1), 11(2) or wafer transfer processing in the opposite direction, the two wafer transfer processes included in this wafer transfer processing can be performed independently. As a result, the throughput of the CVD apparatus can be improved.

(2) Also, in the above embodiments, the case was described in which the present invention was applied to a CVD apparatus such that wafer deposition part 10 comprises wafer standby chambers 12(1), 12(2) and a water transfer chamber 14. However, the present invention can also be applied to a CVD apparatus not having the wafer standby chambers 12(1), 12(2) or the wafer transfer chamber 14, That is, it can also be applied to a CVD apparatus in which the wafer 51 is directly transferred between the cassette 52 and the reaction chambers 11(1) and 11(2).

(3) Also, in the above embodiments, the case where the present invention was applied to a single wafer cluster type CVD apparatus was described. However, the present invention could also be applied to CVD apparatuses of other types than this. For example, the present invention could also be applied to a batch type CVD apparatus.

(4) Also, in the above embodiments, the case where the present invention was applied to a CVD apparatus was described. However, the present invention could also be applied to wafer processing apparatuses other than CVD apparatuses. For example, the present invention could also be applied to wafer etching apparatuses.

(5) Also, in the above embodiments, the case where the present invention was applied to a wafer processing apparatus in which wafers of semiconductor devices were processed was described. However, the present invention could also be applied to substrate processing apparatuses that process substrates of solid-state devices other than semiconductor devices. For example, the present invention could also be applied to a glass substrate processing apparatus that processes glass substrates of a liquid crystal display apparatus.

(6) Apart from this, the present invention could of course be put into practice modified in various ways without departing from the scope of its essence.

As described in detail above, with the substrate processing apparatus according to the first and the ninth invention. when the substrate is transferred between the substrate introduction position and the substrate processing part, the substrate is transferred through a sealed space cleansed by inert gas. Contamination of the substrate by a natural oxide film etc during the period in which it is being transferred between the apparatuses can thereby be prevented.

With the substrate processing apparatus according to the second invention, in an apparatus according to the first invention, the substrate holding part constitutes a buffering mechanism of the transfer part side substrate transfer processing and the processing part side substrate transfer processing. Independence of the two transfer processes can thereby be achieved. As a result, the throughput of the substrate processing apparatus can be improved.

With the substrate processing apparatus of the third invention, in an apparatus according to the second invention, the substrate holding part is constituted by a substrate mounting shelf. The substrate holding part can thus be constructed in a brief manner.

With the substrate processing apparatus of the fourth invention, in an apparatus according to the third invention, the substrate mounting shelf, as the substrate introduction/removal ports, comprises the transfer part side substrate Introduction/removal port and the processing part side substrate introduction/removal port. Thus, even when access of the substrate mounting shelf by the transfer part side substrate transfer part and processing side substrate transfer part occurs simultaneously, there is no need to effect adjustment in respect of conflict thereof. As a result, the throughput of the substrate processing apparatus can be improved.

With the substrate processing apparatus of the fifth invention, in an apparatus according to the fourth invention, the difference of access directions of the substrate mounting shelf by the transfer part side substrate transfer part and the processing part side substrate transfer part is absorbed by suitably setting at least one of the positions, orientations and widths of the transfer part side substrate introduction/removal port and processing part side substrate introduction/removal port. In this way, the difference in access direction can be absorbed by a brief construction.

With the substrate processing apparatus according to the sixth invention, in an apparatus according to the fifth invention, the substrate mounting shelf is constructed so as to hold the substrate using a plurality of support pillars having grooves in which the periphery of the substrate is inserted. Also, the positions. orientations, width and depth of the transfer part side substrate introduction/removal port and the processing part side substrate introduction/removal port are suitably set by suitable setting of the depths of the grooves and the position of arrangement of the support pillars. Thus, the position, orientation and width of the transfer part side substrate introduction/removal port and processing part side substrate introduction/removal port can be suitably set by means of a brief construction.

With the substrate processing apparatus according to the seventh invention, In an apparatus according to the fourth invention. there is provided a rotary drive part that drives the substrate mounting shelf In rotation. It is thereby possible to employ as the substrate mounting shelf a substrate mounting shelf identical with that which would be used if the direction of access of the substrate mounting shelf by the transfer part side substrate transfer part and the processing part side substrate transfer part were the same. This facilitates manufacture of the substrate mounting shelf.

Also. a substrate mounting shelf having two plate-shaped support pillars can be employed as the substrate mounting shelf. The substrate can thereby be held in stable fashion.

Also, as a result, the access directions of the substrate mounting shelf by the transfer part side substrate transfer part and processing part side substrate transfer part can be aligned. The crystal orientation of the substrate in the substrate processing space can thereby be set to a desired orientation. As a result, impairment of the substrate processing characteristics caused by this crystal orientation being offset from the desired orientation can be prevented.

With the substrate processing apparatus according to the eighth invention, in a substrate processing apparatus according to the first invention, inert gas supply processing is performed only when the oxygen concentration of the transfer part side substrate transfer space is less than the prescribed value. The consumption of inert gas can thereby been reduced compared with a construction in which inert gas is constantly supplied.

What is claimed is:

1. A substrate processing apparatus comprising:
a substrate processing part provided in a position different from a substrate Introduction position where a substrate accommodated in a substrate accommodating body of sealed construction having a substrate introduction/removal port at the side is introduced, that performs prescribed processing on said substrate; and
a substrate transfer part that transfers said substrate between said substrate introduction position and said substrate processing part; and
said substrate transfer part comprises:
a plurality of substrate accommodating body holding. parts each of which holds respectively said substrate accommodating body, provided at said substrate introduction position;
a transfer part side substrate transfer space provision part that provides a sealed substrate transfer space which is a space for transferring said substrate between said substrate accommodating body that is held in said substrate accommodating body holding part and said substrate processing part and pressure of which is set at atmospheric pressure;
a cleansing part that cleanses with inert gas said transfer part side substrate transfer space when said substrate is transferred between said substrate accommodating body held in said substrate accommodating body holding part and said substrate processing part;
a substrate introduction/removal port opening/closing part that opens/closes the substrate introduction/removal port of said substrate accommodating body held in said substrate accommodating body holding part in a condition in which said transfer part side substrate transfer space has been cleansed by said cleansing part, arranged in said transfer part side substrate transfer space; and
a transfer part side substrate transfer part that transfers said substrate between said substrate accommodating body in which said substrate introduction/removal port has been opened by said substrate introduction/removal port opening/closing part and said substrate processing part, arranged in said transfer part side substrate transfer space.

2. The substrate processing apparatus according to claim 1 wherein said substrate processing part comprises:
a substrate processing space provision part that provides a sealed substrate processing space for performing said prescribed processing on said substrate;
a substrate standby space provision part that provides a sealed substrate standby space for temporarily holding said substrate in standby;
a processing part side substrate transfer space provision part that provides a sealed processing part side substrate transfer space for transferring said substrate between said substrate standby space and said substrate processing space;
a processing part side substrate transfer part that transfers said substrate between said substrate standby space and said substrate processing space, arranged in said processing part side substrate transfer space; and
a substrate holding part that holds said substrate that is transferred into said substrate standby space, arranged in said substrate standby space.

3. The substrate processing apparatus of claim 2 wherein said substrate holding part is a substrate mounting shelf comprising a substrate introduction/removal port through which introduction/removal of said substrate is effected.

4. The substrate processing apparatus of claim 3 wherein said substrate mounting shelf. as said substrate introduction/removal ports, comprises;
a transfer part side substrate introduction/removal port through which introduction/removal of said substrate is performed by said transfer part side substrate transfer part; and
a processing part side substrate introduction/removal port through which introduction/removal of said substrate is performed by said processing part side substrate transfer part.

5. The substrate processing apparatus of claim 4 wherein the access directions of said substrate mounting shelf by said transfer part side substrate transfer part and said processing part side substrate transfer part are set in different directions, and
said substrate mounting shelf is constructed so as to absorb the difference of said access directions by suitable setting of at least one of the positions, orientations and widths of said transfer part side substrate introduction/removal port and said processing part side substrate introduction/removal port.

6. The substrate processing apparatus according to claim 5 wherein said substrate mounting shelf is constructed so as to hold said substrate by means of a plurality of support pillars having grooves in which the periphery of said substrate is inserted;
said transfer part side substrate introduction/removal port and said processing part side substrate introduction/removal port of said substrate mounting shelf being respectively set between two adjacent support pillars of said plurality of support pillars; and
when the positions of said transfer part side substrate introduction/removal port and said processing part side substrate introduction/removal port are suitably set, the positions are set by suitable setting of the depths of said grooves;
when the orientations of said transfer part side substrate introduction/removal port and said processing part side substrate introduction/removal port are suitably set, the orientations are set by suitable setting of the position of arrangement of said two adjacent support pillars; and
when the widths of said transfer part side substrate introduction/removal port and said processing part side substrate introduction/removal port are suitably set, the widths are set by suitable setting of the position of arrangement of said two adjacent support pillars.

7. The substrate processing apparatus according to claim 4 wherein the access directions of said substrate mounting shelf by said transfer part side substrate transfer part and said processing part side substrate transfer part are set in different directions;
said substrate processing apparatus further comprises a rotary drive part that drives said substrate, mounting shelf in rotation; and
said rotary drive part is constructed:
such that the rotary drive part drives said substrate mounting shelf in rotation so that, when said substrate mounting shelf is accessed by said transfer part side substrate transfer parts said transfer part side substrate introduction/removal port faces the direction of access of said substrate mounting shelf by said transfer part side substrate transfer part; and
such that the rotary drive part drives said substrate mounting shelf in rotation so that, when said substrate mounting shelf is accessed by said processing part side substrate transfer part, said processing part side substrate introduction/removal port faces the direction of access of said substrate mounting shelf by said processing part side substrate transfer part.

8. The substrate processing apparatus according to claim 1 wherein said cleansing part comprises:
a vacuum evacuation part that evacuates the atmosphere of said transfer part side substrate transfer space;
an inert gas supply part that supplies inert gas to said transfer part side substrate transfer space;
an oxygen concentration detection part that detects-the oxygen concentration of said transfer part side substrate transfer space; and
a control part that controls the operation of said inert gas supply part such that, if the oxygen concentration detected by this oxygen concentration detection part exceeds a prescribed value, supply processing of said inert gas is conducted and if it is less than the prescribed value this supply processing is stopped.

9. A substrate processing method wherein when a substrate is transferred between a plurality of substrate accommodating body holding parts each of which holds respectively a substrate accommodating body of sealed construction having a substrate introduction/removal port at the side, provided at a substrate introduction position where said substrate accommodated in the substrate accommodating body is introduced and a substrate processing part where prescribed processing is performed on said substrate, provided at a position different from said substrate introduction position, said substrate is transferred through a sealed space cleansed by inert gas.
